(19) United States
(12) Patent Application Publication
(10) Pub. No.: US 2005/0232039 A1
(43) Pub. Date: Oct. 20, 2005

(54) APPARATUS AND METHOD THEREOF FOR MULTIPLE-TIME PROGRAMMING USING ONE-TIME PROGRAMMING DEVICE

(76) Inventor: Jerry Hsu, Tainan City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/905,896

(22) Filed: Jan. 25, 2005

(30) Foreign Application Priority Data
Apr. 14, 2004 (TW) 93110325

(51) Int. Cl. G11C 29/00

(52) U.S. Cl. 365/201

(57) ABSTRACT

An apparatus for multiple-time programming using one-time programming (OTP, hereinafter) and method thereof are provided. The apparatus includes a selecting unit, a first option OTP device, a second option OTP device, and a selecting OTP unit. One of the first OTP signal and the second OTP signal outputted from the first option OTP device and the second option OTP device respectively is selected according to the selecting signal outputted from the selecting OTP device according to the selecting unit. With the apparatus and method thereof, drawbacks of unchangeable OTP device provided as written and high cost of multiple-time programmable devices are thus eliminated.

### CROSS-REFERENCE TO RELATED APPLICATION

This application claims the priority benefit of Taiwan application serial no. 93110325, filed on Apr. 14, 2004.

### BACKGROUND OF THE INVENTION

1. Field of Invention

The present invention relates to an integrated circuit, and more particularly, to an apparatus and method thereof for multiple-time programming using one-time programming (OTP) devices.

2. Description of the Related Art

In a proceeding of an integrated circuit manufacture, the electrical parameters of each integrated circuit may vary from lot to lot, and vary from wafer to wafer of the same lot, and even vary from die to die of the same wafer. There are different process variations such as deviation of ion implantation, deviation of gate oxide thickness, and error in etching. Such variation of process will cause frequency deviation of an oscillator, or voltage deviation of a regulator. If the electrical parameters of an integrated circuit vary beyond the specification, e.g. over 5% deviation of the IC specification, the product is identified culling during testing process. Therefore, the IC manufacturer should perform some post-fabrication fine-tuning of the parameters mentioned above for increasing production yield. Since the parameters mentioned above change along with fabricating parameters, one-time programming device, e.g. fuse and metal wire, is used for post-fabrication fine-tuning for electrical parameter consistency within a lot. Generally speaking, yield is effectively improved with the fine-tuning methods for the IC after fabrication.

A common OTP option method used for integrated circuit includes laser trim and poly fuse, a.k.a. E-fuse. The OTP device programming using laser trimming is to blow a metal wire with high-energy laser. On the other hand, to program a OTP device using poly fusing is to blow the poly wire therein with large current or change resistance of the poly wire with electron migration phenomenon under large current. Checking the resistance of the metal wire or poly wire, e.g. whether is open circuit or not, it is known that if the OTP device is programmed yet. The programming process is irreversible, i.e. once an OTP device being blowed, it cannot be recovered to the un-blowed state.

When using an OTP device, e.g. a poly fuse, once the device is programmed (blowed), it is not programmable anymore, that is, parameters thereof are not re-adjustable. However, from user's point of view, user would like to re-program the parameters of the device even after is fine-tuned by the IC manufacturer. For example, for a STN LCD driver IC, the operating voltage VLCD of the STN LCD driving waveform has been adjusted to a precise value during the testing process, yet the LCD module might suffer production yield from liquid crystal characteristic migration or the gap deviation of electrode on glass. Therefore 5% culling are found as contrast ratio of the STN LCD products might migrate, and the STN LCD module maker would hope to fine-tune the VLCD of the STN LCD driver again, so as to raise production yield of the STN LCD modules. In conventional technology, multiple-time programming (MTP) devices are used for re-programmable purpose, including an erasable programmable read only memory (EPROM), an electrically erasable programmable read only memory (EEPROM), a flash memory, for example. However, MTP devices are manufactured more costly. For example, for a STN LCD driver IC, a 0.35 μm 3.3V/18V high voltage process is used, yet if a MTP device such as EEPROM is to be integrated, several additional masks are required, coming along with higher cost, longer fabricating time, and later lead time. More mask procedures refer to lower yield, and fewer foundries are capable of MTP devices. Therefore, MTP devices are not compatible to most of the foundries in the industry, which means manufacturing capacity is hardly distributed.

### SUMMARY OF THE INVENTION

According to one aspect of the present invention, an apparatus for multiple-time programming using one-time-programming (OTP) devices is provided. Multiple-time programming is realized for the apparatus with using OTP devices instead of using MTP devices, and manufacturing cost is lowered.

According to another aspect of the present invention, an apparatus for multiple-time programming using OTP devices is provided. Different option OTP devices are selected such that different parameters are written for different time. The apparatus in the present invention is thus multiple-time programmable without the one-time programmable limitation of the conventional OTP device.

The present invention provides an apparatus for multiple-time programming using OTP devices, including a first option OTP device for outputting a first OTP signal, a second option OTP device for outputting a second OTP signal, a selecting OTP device for outputting a selecting signal, and a selecting unit. Wherein the selecting unit is coupled to the first option OTP device, the second option OTP device, and the selecting OTP device, for selecting one signal between the first OTP signal and the second OTP signal according to the selecting signal.

The present invention provides an apparatus for multiple-time programming using OTP devices, including N+1 option OTP devices, N selecting OTP devices, and N selecting units. The N+1 option OTP devices are sequentially named as the first, the second, . . . and the N+1^{th} option OTP device. The N selecting OTP devices are sequentially named as the first, the second, . . . and the N^{th} selecting OTP device. The N selecting units are sequentially named as the first, the second, . . . and the N^{th} selecting unit, where N is an integer. Each of the option OTP devices outputs an OTP signal, each of the selecting OTP devices outputs a selecting signal, and each of the selecting unit outputs an option signal. Wherein the N^{th} selecting unit is coupled to the N+1^{th} option OTP device, the N−1^{th} selecting unit and the N^{th} selecting OTP device, such that one of the option signal outputted from the N+1^{th} option OTP device and the option signal outputted from the N−1^{th} selecting unit is selected for outputting according to the selecting signal outputted from the N^{th} selecting OTP device. And the first selecting unit is coupled to the first option OTP device, the second option OTP device and the first selecting OTP device, such that one of the option signals outputted from the first option OTP device and the second option OTP device is selected for outputting according to the selecting signal outputted from the first selecting OTP device.

According to another aspect of the present invention, a method for multiple-time programming using OTP device is provided, including providing N+1 option OTP devices, sequentially named as the first, the second, . . . and the N+1^{th} option OTP device, each of the option OTP devices outputs an OTP signal. Also providing N selecting OTP devices, sequentially named as the first, the second, . . . and the N^{th} selecting OTP device, each of the selecting OTP device outputs a selecting signal. Selecting one signal between the OTP signals outputted from the first option OTP device and the second option OTP device according to the selecting signal outputted from the first selecting OTP device as the first option signal. And selecting one signal between the OTP signals outputted from the N+1^{th} option OTP device and the option signal outputted from the N−1^{th} selecting unit according to the selecting signal outputted from the N^{th} selecting OTP device for output.

The method as described above, wherein the initial values of the selecting signals of the selecting OTP devices serve to select the N−1^{th} option signal for outputting between the OTP signals outputted from the N+1^{th} option OTP device and the N−1^{th} option signal. The initial value of the selecting signal of the first selecting OTP device serves to select the OTP signal outputted from the first option OTP device for outputting between the first option OTP device and the second option OTP device.

In one aspect of the present invention, when programming the integrated circuit in the present invention for the first time, the method further includes writing the first option data into the first option OTP device. When programming the integrated circuit for the second time, writing the second option data into the second option OTP device, and setting the first selecting OTP device such that the OTP signal outputted from the second OTP option device is selected between the OTP signal outputted from the second option OTP device and the OTP signal outputted from the first option OTP device. When continuing programming the integrated circuit, writing the N+1^{th} option data into the N+1^{th} option OTP device, and setting the N^{th} option OTP device, such that the OTP signal outputted from the N+1^{th} OTP device is selected between the OTP signal outputted from the N+1^{th} OTP option device and the option signal from N−1^{th} selecting unit.

For those skills in the art, the apparatus described above further includes a writing unit coupled to the option OTP devices and the selecting OTP devices, for writing the option data into the option OTP devices and selecting data into the selecting OTP devices. Furthermore, in one aspect of the present invention, the OTP devices can be metal wires or poly fuses, wherein the metal wires can be adjusted by laser trimming, and the poly fuses can be adjusted by high current, yet the scope of the present invention is not limited to the mentioned devices.

The apparatus for multiple-time programming uses OTP devices instead of MTP devices with similar function but costs less; from users' point of view, the OTP devices in the present invention serve as multiple-time programmable devices. Moreover, since fabricating steps are simplified, more foundries and processes for manufacturing the devices are capable of manufacturing the devices in the present invention, and yield and cost issues are improved.

### BRIEF DESCRIPTION OF THE DRAWINGS

FIG. 1 is a schematic block diagram illustrating an apparatus for two-time programming using one-time programming devices according to an embodiment of the present invention.

FIG. 2 is a schematic block diagram illustrating an apparatus for multiple-time programming using one-time programming devices according to an embodiment of the present invention.

### DESCRIPTION OF THE EMBODIMENTS

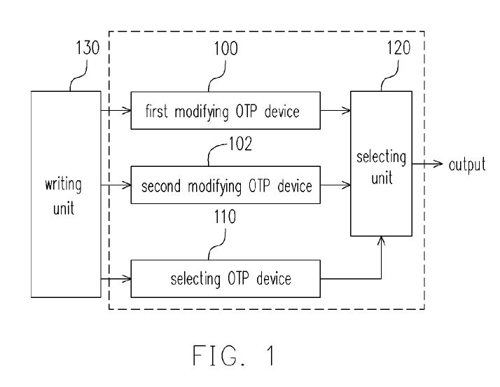

Referring to FIG. 1, it illustrates a schematic block diagram of an apparatus for two-time programming using one-time programmable (OTP) device according to one embodiment of the present invention.

According to the figure, the apparatus includes a selecting unit 120, coupled to a first option OTP device 100, a second option OTP device 102, and selecting OTP device 100. The apparatus further includes a writing unit 130, coupled to the first option OTP device 100, the second option OTP device and the selecting OTP device 110.

As the integrated circuit according to the present invention is fabricated, the initial value of selecting OTP device 110 serves to select the OTP signal outputted from the first option OTP device 100, and is outputted from the selecting unit 120 as the option signal. When first time programming the integrated circuit, the writing unit 130 writes the first option data into the first option OTP device 100. According to the initial setting of the selecting OTP device 110, the selecting unit 120 receives the first OTP signal outputted from the first option OTP device written with the first option data, and outputs which as the option signal. Thereafter, when a new option data needs to be re-programmed, the writing unit 130 serves to change the setting of the selecting OTP device 110, such that the setting of the selecting OTP device 110 is changed by the writing unit 130, and the second option OTP device 102 is selected by the selecting signal outputted from the selecting OTP device 110. Moreover, the writing unit 130 writes the second option data into the second option OTP device 102, and outputting the second OTP signal via the second option OTP device 102, receiving the second OTP signal via the selecting unit 120, and outputting as the option signal.

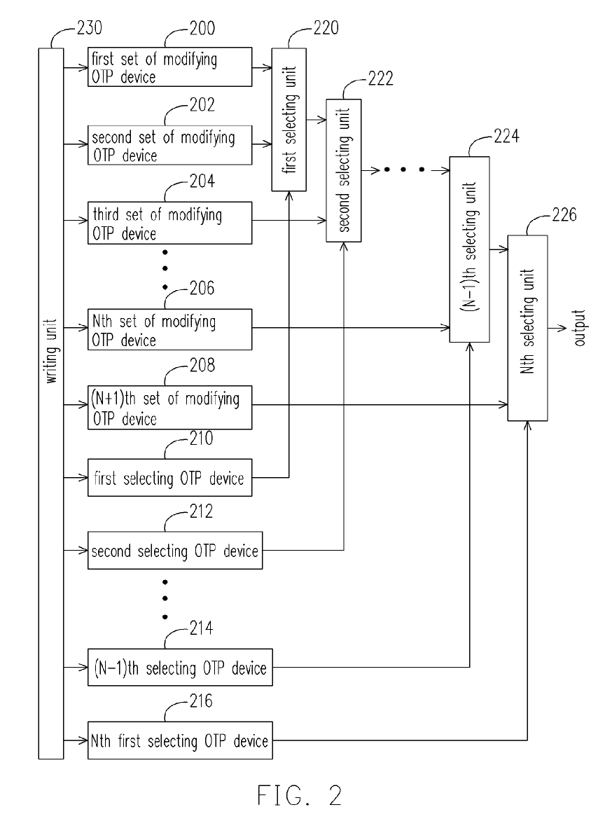

Similarly, according to the embodiment in the present invention as described above, when multiple-time programmable apparatus is needed, referring to an apparatus for multiple-time programming using OTP device according to one embodiment of the present invention illustrated in FIG. 2.

The apparatus according to the embodiment includes N+1 option OTP devices 200˜208, N selecting OTP devices 210˜210, and N selecting units 220˜226, respectively named as a first option OTP device 200, a second option OTP device 202, . . . and a N+1^{th} option OTP device 208; a first selecting OTP device 210, a second selecting OTP device 212, . . . and a N^{th} selecting OTP device 216; and a first selecting unit 220, a second selecting unit 222, . . . and a N^{th} selecting unit 226. [Para 24] Wherein, the first selecting unit 220 is coupled to the first option OTP device 200, the second option OTP device 202, and the first selecting OTP device 210. The N^{th} selecting unit 226 is coupled to the N+1^{th} option OTP device 208, the N−1^{th} selecting unit 224, and the N^{th} selecting OTP device 216. According to the selecting signal outputted from the first selecting OTP device 210, one of the OTP signals outputted between the first option OTP device 200 and the second option OTP device 202 is selected by the first selecting unit 220. According to the selecting signal outputted from the N^{th} selecting OTP device 216, one of the signals is selected between the signal outputted from the N−1^{th} selecting unit 224 and the OTP signal outputted from the N+1^{th} option OTP device 208.

Wherein, the selecting signals outputted according to the initial values of the selecting OTP devices 210˜216 serves to select the N−1^{th} option signal between the OTP signal outputted from the N+1^{th} option OTP device 208 and the N−1^{th} option signal by the N^{th} selecting unit 226. Whereas the initial value of the selecting signal outputted from the first selecting OTP device 210 serves to select the OTP signal outputted from the first option OTP device 200 between the OTP signals outputted from the first option OTP device 201 and the second option OTP device 202 by the first selecting unit 220.

As programming the apparatus for the first time, the writing unit 230 writes the first option data into the first option OTP device 200. According to the initial setting of the first selecting OTP device 210, the first selecting unit 220 receives the written first option data in the first option OTP device 200 between the first option OTP device 200 and the second option OTP device 202, and outputs the first option signal. The second selecting unit 222 receives the first option signal and outputs as the second option signal selected between the first option signal and the third option OTP device 204. Similarly, the N^{th} selecting unit 226 receives the N−1^{th} option signal selected between the N−1^{th} option signal and the N+1^{th}option OTP device 208, and outputs as the N^{th} option signal. Accordingly, the final output value is the first option data located in the first option OTP device 200.

As programming the integrated apparatus in the present invention for the second time, the writing unit 230 writes the second option data into the second option OTP device 202, and changes the setting of the first selecting OTP device 210. The first selecting unit 220 receives the second option data written in the second option OTP device 202 and outputs the first option signal that is selected between the first option OTP device 200 and the second option OTP device 202. The second selecting unit 222 receives the first option signal and outputs as the second option signal that is selected between the first option signal and the third option OTP device 204. Similarly, the N^{th} selecting unit 226 receives the N−1^{th} option signal and outputs as the N^{th} option signal that is selected between the N−1^{th}option signal and the N+1^{th}option OTP device 208. Accordingly, the final output value is the second option data located in the second option OTP device 202.

When a new option data needs to be re-programmed, the writing unit 230 writes the N+1^{th} option data into the N+1^{th} option OTP device 208, and changes the setting of the N^{th} selecting OTP device 216 such that the OTP signal outputted from the N+1^{th} option OTP device 208 is outputted as the N^{th} option signal selected between the option OTP signal outputted from the N+1^{th} option OTP device 208 and the N−1^{th} option signal.

The present invention provides a method for multiple-time programming using OTP devices, besides an apparatus thereof; the method includes the following steps.

Providing aforementioned N+1 option OTP devices 200˜208 for outputting OTP signals, and providing selecting OTP devices 210˜216 outputted N selecting signals.

Selecting one between the option OTP signals outputted from the first option OTP device 200 and the second option OTP device 202, and outputting a first option signal according to the selecting signal outputted from a first selecting OTP device 210. Selecting one between the option OTP signals outputted from the third option OTP device 204 and the first option signal, and outputting the second option signal according to the selecting signal outputted from the second selecting OTP device 212. Similarly, selecting one from the OTP signal outputted from the N+1^{th} option OTP device 208 and the N−1^{th} option signal according to the selecting signal outputted from the N^{th} selecting OTP device 216.

Wherein, the initial values of the selecting signals outputted from the OTP devices 210˜216 serve to select the N−1^{th} option signal between the OTP signal outputted from the N+1^{th} option OTP device 108 and the N−1^{th} option signal before outputting. The selecting signal outputted from the first selecting OTP device 210 according to the initial value thereof serves to select the OTP signal outputted from the first option OTP device 200 between the first OTP device 200 and the second option OTP device 202 before outputting as the option signal.

When programming the apparatus in the present invention for the first time, the writing unit 230 writes the first option data into the first option OTP device 200. According to the initial settings of the first selecting OTP device 210, the setting of the first selecting OTP device 210 serves to select the first option data written into the first option OTP device 200 between the first option OTP device 200 and the second option OTP device 202 before outputting. The setting of the second selecting OTP device 212 serves to select the first option signal between the first option signal and the third option OTP device 204 before outputting as the second option signal. Similarly, the setting of the N^{th} selecting OTP device 216 serves to select the N−1^{th} option signal between the N−1^{th} option signal and the N+1^{th} option OTP device 208 before outputting as the N^{th} option signal. Accordingly, the final output value is the first option data located in the first option OTP device 200.

As programming the apparatus for the second time in the present invention, the writing unit 30 writes the second option data into the second option OTP device 202, and changes the setting of the first selecting OTP device 210. The setting of the first selecting OTP device 210 serves to select the second option OTP device written with the second option data between the first option OTP device 200 and the second option OTP device 202 before outputting as the first option signal. The setting of the second selecting OTP device 212 serves to select the first option signal between the first option signal and the third option OTP device 204 before outputting as the second option signal. Similarly, the setting of the N^{th} selecting OTP device 216 serves to select the N−1^{th} option signal between the N−1^{th} option signal and the N+1^{th} option OTP device 208 before outputting as the N^{th} option signal. Accordingly, the final output value is the second option data located in the second option OTP device 202.

As a new option data needs to be re-programmed, the writing unit 230 writes the N+1^{th} option data into the N+1^{th} option OTP device 208 and changes the settings of the N^{th} selecting OTP device 216, such that the OTP signal outputted from the N+1^{th} option OTP device 208 is selected between the OTP signals outputted the N+1^{th} option OTP device 208 and the N−1^{th} option signal.

Similarly, when N+1 option OTP devices are provided, a number of N+1 times programming opportunities for option data is available. Thus, from users' aspect, the apparatus for multiple-time programming using OTP devices and method thereof manages to select different OTP devices according to different selecting signals to perform multiple-time programming thereby similarly to using MTP devices, i.e. option data can be repeatedly written. Since OTP devices are fabricated more simply than MTP devices, the fabrication cost is lowered, and more capable foundries are available as well.

Although the invention has been described with reference to a particular embodiment thereof, it will be apparent to those skilled in the art that modifications to the described embodiment may be made without departing from the spirit of the invention. Accordingly, the scope of the invention will be defined by the attached claims and not by the above detailed description.

1. An apparatus for multiple-time programming using one-time programming (OTP) device, comprising:
a first option OTP device, outputting a first OTP signal;
a second option OTP device, outputting a second OTP signal;
a selecting OTP unit, outputting a selecting signal; and
a selecting unit, coupled to the first option OTP device, the second option OTP device, and
the selecting OTP device, for selecting one of the first OTP signal and the second OTP signal to output according to the selecting signal.

2. The apparatus as recited in claim 1 further comprising a writing unit, coupled to the first option OTP device, the second option OTP device, and the selecting OTP device, for writing a first option data into the first option OTP device and writing a second option data into the second option OTP device and writing a selecting data into the selecting OTP unit.

3. The apparatus as recited in claim 1, wherein the first option OTP device, the second option OTP device, and the selecting OTP device comprise poly fuses that are adjustable with current.

4. The apparatus as recited in claim 1, wherein the first option OTP device, the second option OTP device, and the selecting OTP device comprise metal wires that are adjustable with laser.

5. The apparatus as recited in claim 1, wherein the first option OTP device, the second option OTP device, and the selecting OTP unit comprise devices that are programmable for at least one time.

6. The apparatus as recited in claim 1, wherein the first option OTP device, the second option OTP device, and the selecting OTP unit are respectively selected one from a group of an Erasable Programmable Read-Only-Memory (EPROM), an Electrically Erasable Programmable Read-Only-Memory (EEPROM), and a FLASH memory.

7. An apparatus for multiple-time programming using one-time programming (OTP) device, comprising:
N+1 option OTP devices, sequentially named as a first option OTP device, a second option OTP device, . . . and a N+1^{th} option OTP device, wherein each of the N+1 option OTP devices outputs an OTP signal, where N is an integer;
N selecting OTP device, sequentially named as a first selecting OTP device, a second selecting OTP device, . . . and a N^{th} selecting OTP device, wherein each of the N selecting OTP devices outputs a selecting signal; and
N selecting units, named as a first selecting unit, a second selecting unit, . . . and a N^{th} selecting unit, wherein each of the N selecting units outputs a option signal,
wherein the N^{th} selecting unit is coupled to the N+1^{th} option OTP device, the N−1^{th} selecting OTP device, and the N^{th} selecting OTP device, for selecting one signal between the OTP signal outputted from the N+1^{th} selecting OTP device and the option signal outputted from the N−1^{th} selecting unit according to the selecting signal outputted from the N^{th} selecting OTP device,
wherein the first selecting unit is coupled to the first option OTP device, the second option OTP device and the first selecting OTP device, for selecting one signal between the OTP signal outputted from the first option OTP device and the OTP signal outputted from the second option OTP device according to the selecting signal outputted from the first selecting OTP device.

8. The apparatus as recited in claim 7 further comprising a writing unit, coupled to the N+1 option OTP devices and the N selecting OTP devices, for writing a plurality of option data into the N+1 option OTP devices and a plurality of selecting data in the N selecting OTP devices.

9. The apparatus as recited in claim 7, wherein the N+1 option OTP devices and the N selecting OTP devices comprise poly fuses that are adjustable with current.

10. The apparatus as recited in claim 7, wherein the N+1 option OTP devices and the N selecting OTP devices comprise metal wires that are adjustable with laser.

11. The apparatus as recited in claim 7, wherein the N+1 option OTP devices and the N selecting OTP devices comprise devices that are programmable for at least one ti me.

12. The apparatus as recited in claim 7, wherein the N+1 option OTP devices and the N selecting OTP devices are respectively selected one from a group of an Erasable Programmable Read-Only-Memory (EPROM), an Electrically Erasable Programmable Read-Only-Memory (EEPROM), and a FLASH memory.

13. A method for multiple-time programming using one-time programming (OTP) device, comprising:
providing N+1 option OTP devices, sequentially named as a first option OTP device, a second option OTP device, . . . and a N+1^{th} option OTP device, wherein each of the N+1 option OTP devices outputs an OTP signal;
providing N selecting OTP devices, sequentially named as a first selecting OTP device, a second selecting OTP device, . . . and a N^{th} selecting OTP device, wherein each of the N selecting OTP devices outputs a selecting signal;
selecting one between the OTP signal outputted from the first option OTP device and the OTP signal outputted from the second option OTP device according to the selecting signal outputted from the first selecting OTP device, and outputting a first option signal; and selecting one between the OTP signal outputted from the N+1^{th} option OTP device and a N−1^{th} option signal according to the selecting signal outputted from the N^{th} selecting OTP device.

14. The method as recited in claim 13, wherein initial values of the selecting signal outputted from the selecting OTP devices serve to select the N−1^{th} option signal between the OTP signal outputted from the N+1^{th} option OTP device and the N−1^{th} option signal, and an initial value of the first selecting OTP device serves to select the OTP signal outputted from the first option OTP device between the OTP signal outputted from the first option OTP device and the OTP signal outputted from the second option OTP device, the method further comprising:
writing a first option data into the first option OTP device; and
writing a N+1^{th} option data in the N+1^{th} option OTP device, and setting the N^{th} selecting OTP device such that the OTP signal outputted from the N+1^{th} option OTP device is selected between the OTP signal outputted from the N+1^{th} OTP device and a N−1^{th} option signal.

15. The method as recited in claim 13, wherein the N+1 option OTP devices and the N selecting OTP devices comprise poly fuses that are adjustable with current.

16. The method as recited in claim 13, wherein the N+1 option OTP devices and the N selecting OTP devices comprise metal wires that are adjustable with laser.

17. The method as recited in claim 13, wherein the N+1 option OTP devices and the N selecting OTP devices comprise devices that are programmable for at least one time.

18. The method as recited in claim 13, wherein the N+1 option OTP devices and the N selecting OTP devices are respectively selected one from a group of an Erasable Programmable Read-Only-Memory (EPROM), an Electrically Erasable Programmable Read-Only-Memory (EEPROM), and a FLASH memory.
